(19) United States
(12) Patent Application Publication
(10) Pub. No.: US 2008/0290514 A1
(43) Pub. Date: Nov. 27, 2008

(54) Semiconductor device package and method of fabricating the same

(75) Inventors: Young-Lyong Kim, Seongnam-si (KR); Jong-Ho Lee, Asan-si (KR); Chul-Yong Jang, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/154,022

(22) Filed: May 20, 2008

(30) Foreign Application Priority Data
May 21, 2007 (KR) 10-2007-0049320

(51) Int. Cl. H01L 23/498; H01L 21/60

(52) U.S. Cl. 257/738; 438/125; 257/E23.069; 257/E21.511

(57) ABSTRACT

In a semiconductor device, a package including the semiconductor device and a method of forming the same, the semiconductor device package includes a semiconductor device, a wiring board, and an underfill material layer. The semiconductor device includes a semiconductor chip, a metal layer, and solder balls for bump contacts. The semiconductor chip includes an active surface having bonding pads and a rear surface opposite the active surface and having concave portions corresponding to the bonding pads. The metal layer fills the concave portions and covers the rear surface. The solder balls for bump contacts are provided on the bonding pads. The wiring board includes an upper surface to which the semiconductor device is mounted and a lower surface opposite the upper surface. The underfill material layer fills a space between the active surface of the semiconductor device and the upper surface of the wiring board. The semiconductor device and the wiring board are electrically connected to each other by the solder balls for bump contacts of the semiconductor device and bonding electrodes included in the upper surface of the wiring board.

### CROSS-REFERENCE TO RELATED APPLICATIONS

This U.S. non-provisional patent application claims priority under 35 U.S.C. §119 to Korean Patent Application No. 10-2007-0049320, filed on May 21, 2007, the entire contents of which are hereby incorporated by reference.

### BACKGROUND OF THE INVENTION

Embodiments of the present invention relate to a semiconductor device package, and more particularly, to a semiconductor device package having a flip chip structure and a method of fabricating the same.

As semiconductor device applications continue to demand ever higher performance and speed, the number of input/output pins required by semiconductor chips continues to increase. In this regard, there is a limitation on wire bonding used in the semiconductor package fabrication process. Therefore, flip chip (F/C) package configurations have recently received much attention. In an F/C package approach, bumps are used rather than bonding wires for external connectivity.

The bumps electrically and physically connect the semiconductor chip to a wiring board or other substrate. In other words, the bump serves as a connective pathway for electrical signals and operates to physically bond the chip to the wiring board. In order to enhance bonding strength, an underfill material is filled in the space between the semiconductor chip and the wiring board.

The underfill material improves the electrical and physical reliability of a semiconductor device package and also serves as a reinforcing material to counteract thermal stress that is generated arising from a difference in a coefficient of thermal expansion (CTE) between the semiconductor chip and the wiring board when the operating temperature changes. Therefore, the choice of underfill material is an important consideration in the semiconductor device package of an F/C structure for obtaining the thermal/physical reliability of the bumps.

In addition, miniaturization of electronic products requires a low-profile semiconductor device package for compatibility with electronic products of ever-smaller form factors. In this regard, a rear surface of the semiconductor chip is polished, and semiconductor chips having a thickness of about 200 μm or less are commonly used for the semiconductor device package. In order to achieve slim device profiles, some semiconductor device packages include a semiconductor chip having a rear surface that is externally exposed.

In cases where the rear surface of the semiconductor chip of the semiconductor device package is externally exposed, warping of the chip can occur due to a difference between the CTE of silicon in the semiconductor chip and the CTE of a thin-film material present on the circuit surface, i.e., an active surface of the semiconductor chip. The amount of warping can be irrelevant in cases where the rear surface of the semiconductor chip is unpolished. However, when the thickness of the semiconductor chip is reduced in order to form the slim-sized semiconductor device package, limitations can occur in various processes. In addition, such warping can decrease the reliability of the semiconductor device package and can cause fatal defects in device operation.

FIG. 1 is a cross-sectional view of a conventional semiconductor device package.

Referring to FIG. 1, a semiconductor device package may include a semiconductor chip 10, a wiring board 20, solder balls 15 for bump contacts, an underfill material layer 30, a molding material layer 50, and solder balls 28s for external connection.

The semiconductor chip 10 may include bonding pads 12 on an active surface. The semiconductor chip 10 may be mounted on the wiring board 20 through the solder balls 15 for bump contacts. In this manner, the semiconductor device package may be configured as an F/C package.

The wiring board 20 may comprise a system board such as a printed circuit board (PCB). The wiring board 20 may include a core material 22 as a body, an upper insulating layer pattern 24u, and a lower insulating layer pattern 24l. The upper and lower insulating layer patterns 24u and 24l face each other at opposite surfaces of the core material 22 and include bonding electrodes 26u and connecting electrodes 26l, respectively. The bonding electrodes 26u may be electrically connected to the corresponding bonding pads 12 of the semiconductor chip 10 through the solder balls 15 for bump contacts.

The underfill material layer 30 can fill a space between an upper surface of the wiring board 20 and the active surface of the semiconductor chip 10 to bind the semiconductor chip 10 to the wiring board 20. In this manner, the underfill material layer 30 improves the electrical and physical reliability of the semiconductor device package.

The upper surface of the wiring board 20, side portions and a rear surface of the semiconductor chip 10, and the underfill material layer 30 are firmly attached to each other by the molding material layer 50. The molding material layer 50 can operate to protect the semiconductor device package from external chemical or physical exposure. The solder balls 28s for external connection provided on a lower surface of the wiring board 20 may be connected to an internal wiring (not shown) of the wiring board 20 to provide electrical connection between the semiconductor chip 10 and an external circuit.

In the semiconductor device package, as described above, the warping phenomenon may occur due to a difference in a CTE between silicon included in the semiconductor chip 10 and a thin film material on the active surface in cases where the rear surface of the semiconductor chip 10 is polished in order to form a slim-sized semiconductor device package. The warping phenomenon may limit a gap filling process for forming the underfill material layer 30 between the semiconductor chip 10 and the wiring board 20.

Further, since a high-modulus material is often times used for the underfill material layer 30, a solder bonding portion can be relatively hard. Therefore, when the warping phenomenon occurs due to the CTE difference between the semiconductor chip 10 and the wiring board 20, the semiconductor chip 10 and the underfill material layer 30 may become delaminated from the upper insulating layer pattern 24u of the wiring board 20. This, in turn, can decrease the solder joint reliability (SJR) of the resulting semiconductor device package. Additional molding material layer 50 can be provided to prevent decrease in the SJR. However, application of the additional molding material layer 50 can lead to an increased thickness in the semiconductor device package, contrary to the goal of achieving a slim device profile, and can also decrease heat radiation characteristics and increase the fabrication cost of the resulting device.

### SUMMARY OF THE INVENTION

Embodiments of the present specification provide a semiconductor device and a method of fabricating the same capable of reducing the thickness of a semiconductor device package and improving reliability.

Embodiments of the present specification also provide a semiconductor device package and a method of fabricating the same capable of reducing the thickness of the semiconductor device package and improving reliability.

In one aspect, a semiconductor device includes a semiconductor chip including an active surface having bonding pads and a rear surface opposite the active surface and having concave portions corresponding to the bonding pads; a metal layer filling the concave portions and covering the rear surface; and solder balls for bump contacts provided on the bonding pads.

In some embodiments, the corresponding concave portions and bonding pads are vertically arranged relative to the active surface.

In other embodiments, the metal layer includes a material selected from copper, aluminum, tungsten, nickel, gold, and silver, and alloys thereof.

In still other embodiments, a thickness of the semiconductor chip ranges from about 100 μm to about 200 μm.

In even other embodiments, a depth of each concave portion ranges from about 50 μm to about 150 μm.

In another aspect, a method of forming a semiconductor device comprises: preparing a semiconductor substrate where each of semiconductor chips including an active surface having bonding pads and a rear surface opposite the active surface is formed; back-lapping the rear surface; forming concave portions corresponding to the bonding pads on the rear surface; forming a metal layer that fills the concave portions and covers the rear surface; forming solder balls for bump contacts on the bonding pads; and partitioning the metal layer and the semiconductor substrate to divide the semiconductor substrate into respective semiconductor devices.

In some embodiments, the method may further include: attaching the semiconductor substrate to a handling substrate before back-lapping the rear surface; and removing the handling substrate after forming the metal layer.

In other embodiments, the semiconductor chips may be formed to each have a thickness from about 100 μm to about 200 μm by the back-lapping the rear surface.

In still other embodiments, the corresponding concave portions and bonding pads may be vertically arranged with respect to the active surface. The concave portions may be formed using a process selected from ion etching, chemical etching, and laser etching. The concave portions may be formed to have a depth from about 50 μm to about 150 μm.

In even other embodiments, the metal layer may include a material selected from copper, aluminum, tungsten, nickel, gold, and silver, and alloys thereof. The metal layer may be formed using a process selected from inkjet, screen-printing, and deposition.

In another aspect, a semiconductor device package can include: the semiconductor device having the above structure; a wiring board including an upper surface to which the semiconductor device is mounted and a lower surface opposite the upper surface; and an underfill material layer filling a space between the active surface of the semiconductor device and the upper surface of the wiring board. The semiconductor device and the wiring board are electrically connected to each other by the solder balls for bump contacts of the semiconductor device and bonding electrodes included in the upper surface of the wiring board.

In some embodiments, the semiconductor device packages may further include solder balls for external connection provided on the lower surface.

In other embodiment, the underfill material layer may thoroughly cover side surfaces of the semiconductor chip of the semiconductor device.

In another aspect, a method of fabricating a semiconductor device package comprises: preparing the semiconductor device in accordance with the above methods; preparing a wiring board including an upper surface having bonding electrodes corresponding to the solder balls for bump contacts of the semiconductor device and a lower surface opposite the upper surface; mounting the semiconductor device on the wiring board such that the solder balls for bump contacts of the semiconductor device are electrically connected to the bonding electrodes of the wiring board; and forming an underfill material layer filling a space between the active surface of the semiconductor device and the upper surface of the wiring board.

In some embodiments, the methods may further include forming solder balls for external connection on the lower surface.

In other embodiments, the underfill material layer may be formed so as to thoroughly cover side surfaces of the semiconductor chip of the semiconductor device.

### BRIEF DESCRIPTION OF THE FIGURES

The foregoing and other objects, features and advantages of the embodiments of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1 is a cross-sectional view of a semiconductor device package;

FIG. 2 is a cross-sectional view of a semiconductor device package according to an embodiment of the present invention;

FIGS. 3A through 3E are cross-sectional views for illustrating a method of forming a semiconductor device according to an embodiment of the present invention; and

FIGS. 4A through 4C are cross-sectional views for illustrating a method of fabricating a semiconductor device package according to an embodiment of the present invention.

### DETAILED DESCRIPTION OF EMBODIMENTS

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

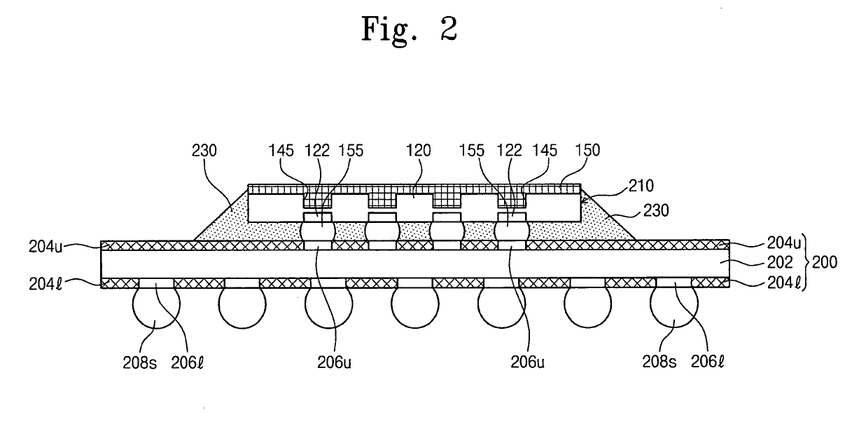

FIG. 2 is a cross-sectional view of a semiconductor device package according to an embodiment of the present invention.

Referring to FIG. 2, a semiconductor device package can include a semiconductor device 210, a wiring board 200, an underfill material layer 230, and solder balls 208s for external connection.

The semiconductor device 210 may include a semiconductor chip 120, a metal layer 150, and solder balls 155 for bump contacts. The semiconductor chip 120 may include an active surface including bonding pads 122 and a rear surface facing the active surface and including concave portions 145 corresponding to the bonding pads 122. The metal layer 150 can cover the rear surface of the semiconductor chip 120 while filling the concave portions 145. The solder balls 155 for bump contacts can be provided on the bonding pads 122. The semiconductor device 210 may be mounted on the wiring board 200 through the solder balls 155 for bump contacts. In this manner, the semiconductor device package illustrated in FIG. 2 can be considered a flip chip (F/C) package.

The metal layer 150 can include a metal material having superior thermal conductivity. For example, the metal material can have thermal conductivity more than about 75 kcal/° C. at about 20° C. The metal material can include, for example, a material selected from copper (Cu), aluminum (Al), tungsten (W), nickel (Ni), gold (Ag), and silver (Au), and alloys thereof.

Since the metal layer 150 covers the rear surface of the semiconductor chip 120 while filling the concave portions 145 corresponding to the bonding pads 122, the semiconductor chip 120 may include regions of relatively increased flexibility in regions proximal to the bonding pads 122 where the thickness is relatively small and more-rigid regions at portions distal to the bonding pads 122, including the edge portions, where the thickness is relatively large. This configuration minimizes the amount of warping in a direction toward the active surface due to a difference in a coefficient of thermal expansion (CTE) between silicon included in the semiconductor chip 120 and a thin film material on the active surface of the semiconductor chip 120, due to the regions of increased flexibility in the regions proximal to the bonding pads 122.

The wiring board 200 may comprise a system board such as a printed circuit board (PCB). The wiring board 200 may include a core material 202 as a body, an upper insulating layer pattern 204u and a lower insulating layer pattern 204l. The upper and lower insulating layer patterns 204u and 204l face each other and include bonding electrodes 206u and connecting electrodes 206l, respectively. The bonding electrodes 206u may be electrically connected to the corresponding bonding pads 122 of the semiconductor device 210 through the solder balls 155 for bump contacts.

The underfill material layer 230 may fill a space between the active surface of the semiconductor device 210 and an upper surface of the wiring board 200 to attach the semiconductor device 210 to the wiring board 200. The underfill material layer 230 operates to improve the electrical/physical reliability of the semiconductor device package.

Solder balls 208s for external connection provided on a lower surface of the wiring board 200 may be connected to an internal wiring (not shown) of the wiring board 200 to provide an electrical connection between the semiconductor device 210 and an external circuit.

In the semiconductor device package having the above structure, the semiconductor device 210 has a slim size and includes the metal layer 150 that covers the rear surface of the semiconductor chip 120 while filling the concave portions 145 formed in the rear surface. This reduces a CTE difference between the wiring board 200 and the semiconductor device 210 and minimizes the amount of warping of the semiconductor device 210. For these reasons, a gap fill process for forming the underfill material layer 230 becomes is more reliable, thereby improving the reliability of the semiconductor device package. In addition, since the semiconductor device package includes the metal layer 150, unlike a typical semiconductor device package that includes an additional molding material layer, the semiconductor device package can enjoy a relatively slim size, heat radiation characteristics can be improved, and fabrication costs can be reduced.

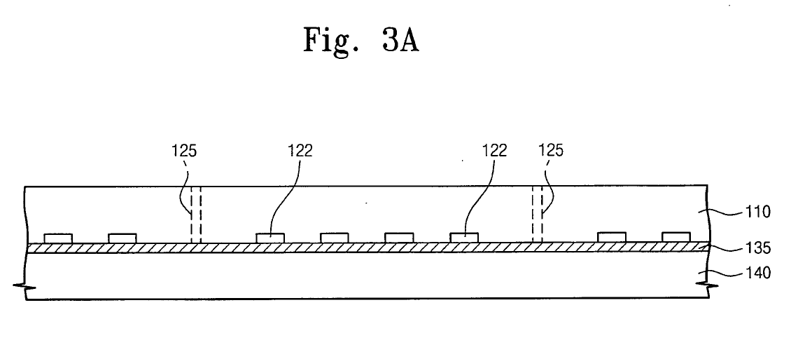

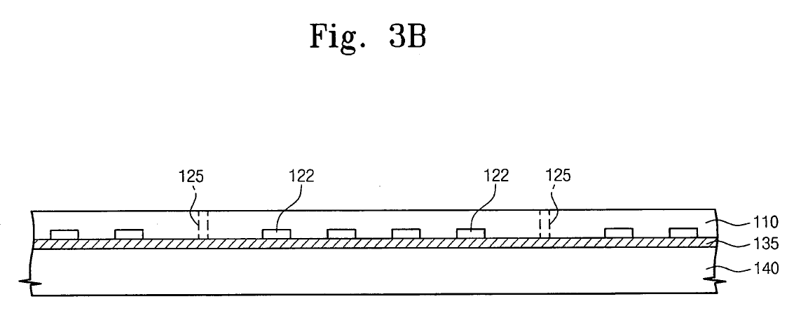

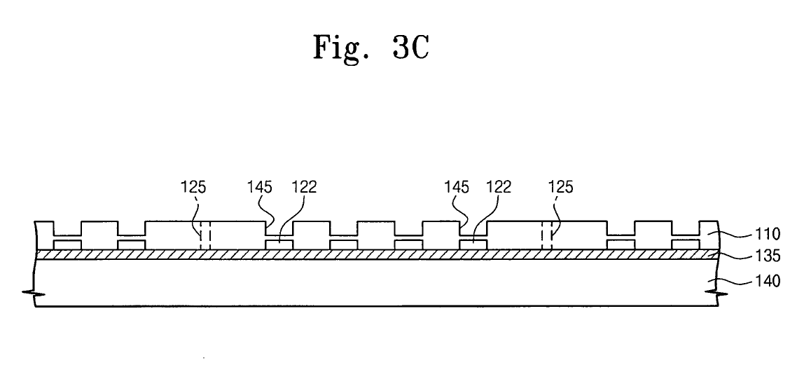

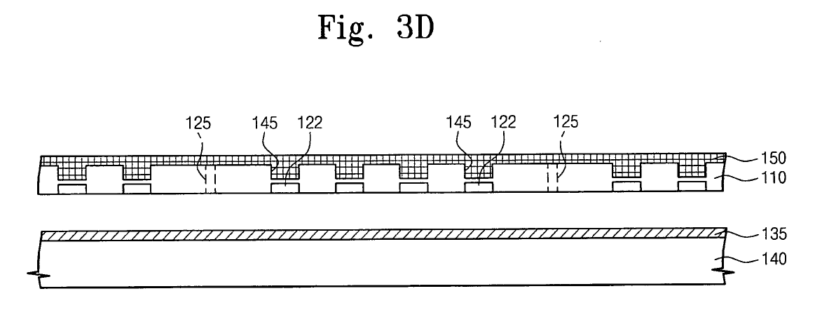

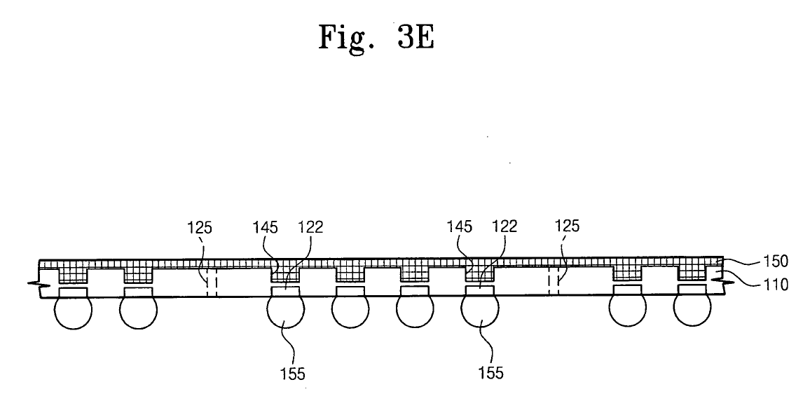

FIGS. 3A through 3E are cross-sectional views for illustrating a method of forming a semiconductor device according to an embodiment of the present invention.

Referring to FIG. 3A, a semiconductor substrate 110 is prepared. Semiconductor chips (not shown), which include active surfaces having bonding pads 122 and rear surfaces facing the active surfaces, are formed in the semiconductor substrate 110.

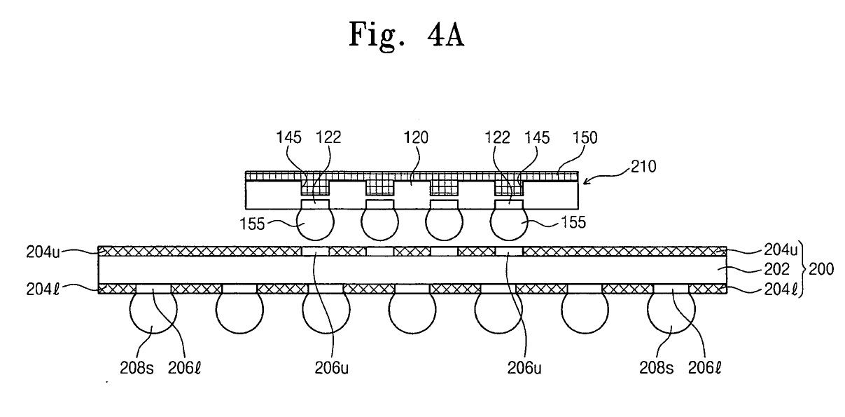

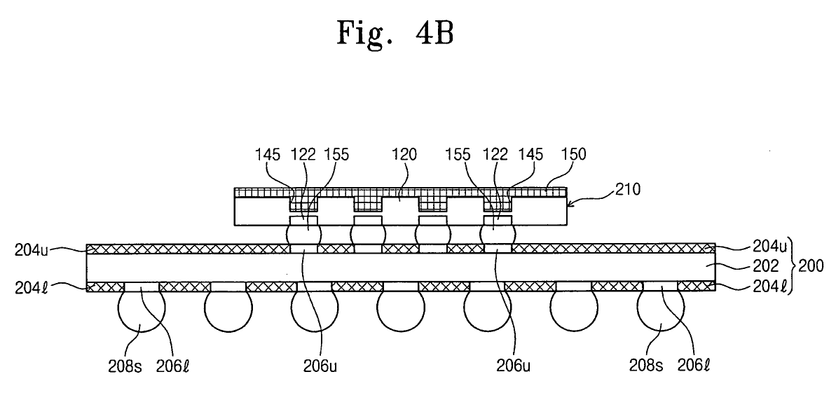

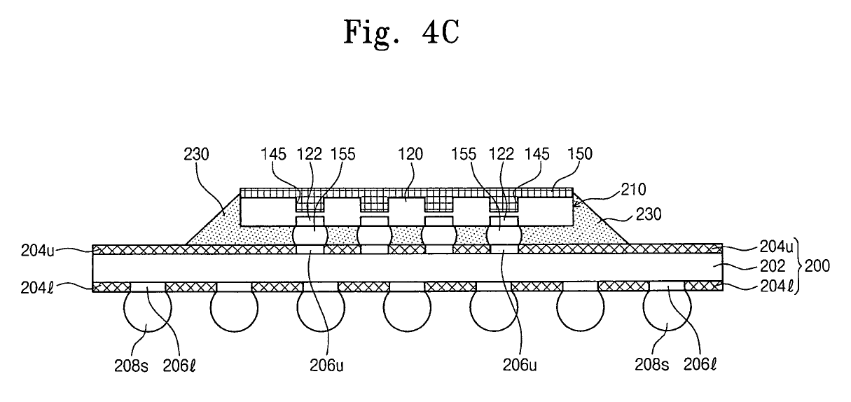

A handling substrate 140 may be attached to the semiconductor substrate 110. The handling substrate 140 may be attached to the active surfaces of the semiconductor chips through an adhesive material layer 135. The handling substrate 140 may relieve a physical stress applied to the semiconductor substrate 110 in a back-lap process for the rear surfaces of the semiconductor chips and repress warping that can occur in the semiconductor substrate 110 when the semiconductor substrate 110 has a small thickness following the back-lap process. Also, scribe lines 125 for dividing the semiconductor substrate 100 into respective semiconductor devices (210, refer to FIG. 4A) may be provided in the semiconductor substrate 110 to partition the semiconductor substrate 110 into discrete chips.

The handling substrate 140 may include a substrate including a material with a coefficient of thermal expansion (CTE) equal or similar to a CTE of the semiconductor substrate 110, e.g., a silicon (Si) substrate or a glass substrate. The handling substrate 140 may have the shape of a disk like the semiconductor substrate 110.

The adhesive material layer 135 may comprise a reworkable adhesive that can be readily separated following adhesion. This is because the handling substrate 140 is removed after back-lapping of the rear surfaces of the semiconductor chips, forming of concave portions that correspond to the bonding pads 122, and forming of a metal layer 150, as will be described below in connection with FIG. 3D, that covers the rear surfaces of the semiconductor chips while filling the concave portions. An adhesive including an ultraviolet (UV) curable resin or a thermoplastic resin may be used as the adhesive material layer 135.

Referring to FIG. 3B, in order to decrease the thickness of the semiconductor chips, the rear surfaces of the semiconductor chips may be back-lapped. The back-lap process of the rear surfaces of the semiconductor chips may include a grinding process to reduce thickness. As a result of the back-lap process, the semiconductor chips may have the thickness ranging from about 100 μm to about 200 μm. In this manner, the semiconductor device and a semiconductor device package having the same may have a relatively small thickness.

In an alternative embodiment, the rear surfaces of the semiconductor chips may be back-lapped, or reduced in the thickness, after the concave portions 145 (refer to FIG. 3C, below) are formed in the rear surfaces of the semiconductor chips.

Referring to FIG. 3C, the concave portions 145 may be formed in the rear surfaces of the semiconductor chips so as to correspond to the bonding pads 122. The concave portions 145 may be formed using, for example, a process selected from ion etching, chemical etching, and laser etching. The concave portions 145 may, for example, have a depth ranging from about 50 μm to about 150 μm. Therefore, the semiconductor chips may include a flexible portion in regions of the concave portions 145 corresponding to the bonding pads 122 having a relatively small thickness and a rigid portion in regions of greater thickness, such as the edge portions. As a result, this configuration operates to minimize warping of the semiconductor chips toward the active surfaces due to a CTE difference between silicon included in the semiconductor chips and a thin film material on the active surfaces.

Referring to FIG. 3D, a metal layer 150 may be formed so as to cover the rear surfaces of the semiconductor chips while filling the concave portions 145 on the rear surfaces. The metal layer 150 can include a metal material having good thermal conductivity. The metal material can, for example, have thermal conductivity of more than about 75 kcal/° C. at about 20° C. The metal material may include a material selected from Cu, Al, W, Ni, Ag, and Au, and alloys thereof. The metal layer 150 may be formed using a fabrication process selected from inkjet, screen-printing, and deposition.

The metal layer 150 can operate to improve the strength of the semiconductor devices. The metal layer 150 can also minimize chipping that is breaking of edges of the semiconductor chips, in a cutting process for the respective semiconductor devices, thereby preventing decrease in quality of the semiconductor devices as a result of the cutting process.

The handling substrate 140 may be removed after the metal layer 150 is formed. The removing of the handling substrate 140 may include irradiation of the adhesive material layer 135 by UV energy or by applying of heat thereto.

Referring to FIG. 3E, solder balls 155 for bump contacts may be formed on bonding pads 122 of the semiconductor chips. The solder balls 155 for bump contacts may be used for connection between the semiconductor chips and a wiring board 200 (refer to FIG. 4A, below). After the solder balls 155 for bump contacts are formed, the semiconductor substrate 110 may be cut along the scribe lines 125 using a substrate cutting apparatus to divide the semiconductor substrate 110 into the respective semiconductor devices.

Alternatively, before removing the handling substrate 140, the semiconductor substrate 110 can be cut and divided into the respective semiconductor devices, and then the solder balls 155 for bump contacts may be formed on the bonding pads 122 of the individual semiconductor devices following removal of the handling substrate 140.

FIGS. 4A through 4C are cross-sectional views for illustrating a method of fabricating a semiconductor device package according to an embodiment of the present invention.

Referring to FIG. 4A, a semiconductor device 210, for example, a semiconductor device formed using the above-described forming method, is prepared. Thereafter, a wiring board 200 is prepared.

The wiring board 200 may include an upper surface including bonding electrodes 206u corresponding to solder balls 155 for bump contacts of the semiconductor device 210 and a lower surface facing the upper surface. The wiring board 200 may be a printed circuit board (PCB). The wiring board 200 may include a core material 202 as a body, an upper insulating layer pattern 204u and a lower insulating layer pattern 204l. The upper and lower insulating layer patterns 204u and 204l may include the bonding electrodes 206u and connecting electrodes 206l, respectively.

Referring to FIG. 4B, the semiconductor device 210 may be mounted on the wiring board 200 such that the solder balls 155 for bump contacts of the semiconductor device 210 are electrically connected to the bonding electrodes 206u of the wiring board 200.

Referring to FIG. 4C, an underfill material layer 230 may be formed so as to fill a space or voids between the active surface of the semiconductor device 210 and the upper surface of the wiring board 200. In one embodiment, the underfill material layer 230 is formed so as to thoroughly cover side surfaces of a semiconductor chip 120 of the semiconductor device 210. Accordingly, the active surface and the side surfaces of the semiconductor chip 120 may be chemically and physically protected from the external environment by the underfill material layer 230, while the rear surface of the semiconductor chip 120 may be chemically/physically protected from the external environment by the metal layer 150.

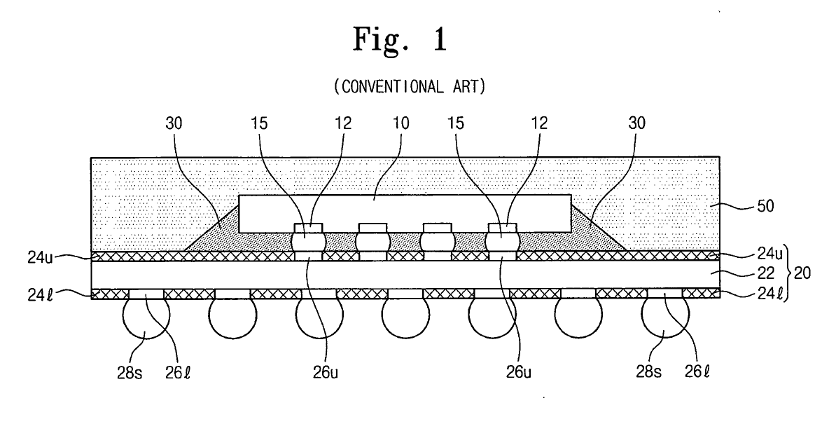

As a result, since the semiconductor chip 120 can be entirely chemically/physically protected from the external environment by the underfill material layer 230 and the metal layer 150, an additional molding material layer (50, refer to FIG. 1, above) is not required. Therefore, a semiconductor device package can be further reduced in thickness, fabrication processes of the semiconductor device package can be simplified, and fabrication costs can be reduced. In addition, since the underfill material layer 230 exposes the metal layer 150 formed on the rear surface corresponding to the active surface of the semiconductor device 210, heat radiation characteristics of the semiconductor device package can be improved.

Solder balls 208s for external connection may be formed on the lower surface of the wiring board 200. The solder balls 208s for external connection may provide electric connection between an external circuit such as a system board (not shown) and the semiconductor device package.

The semiconductor device 210 according to an embodiment of the present invention can include the metal layer 150 that covers the rear surface of the semiconductor chip 120 while filling the concave portions 145 on the rear surface, and thus the semiconductor device 210 can become slim-sized and have improved strength. Therefore, a semiconductor device and a method of fabricating the same capable of forming a slim-sized semiconductor device package and improving the reliability thereof can be provided.

In addition, the semiconductor device package according an embodiment of the present invention can utilize the slim-sized semiconductor device 210 including the metal layer 150 that covers the rear surface of the semiconductor chip 120 while filling the concave portion 145 on the rear surface, and thus the semiconductor device package can become slim-sized and have the improved reliability. Accordingly, a semiconductor device package and a method of fabricating the same, which are adapted for high integration and high reliability, can be provided.

As described above, according to the present invention, a semiconductor device can enjoy reduced thickness and have improved strength by including a metal layer that covers a rear surface of a semiconductor chip while filling concave portions on the rear surface. Therefore, a semiconductor device capable of forming a slim-sized semiconductor device package and improving the reliability thereof can be provided.

Furthermore, according to the present invention, a semiconductor device package can become slim-sized and have the improved reliability by using a slim-sized semiconductor device including a metal layer that covers a rear surface of a semiconductor chip while filling concave portions on the rear surface. Accordingly, a semiconductor device package, which is adapted for high integration and high reliability, can be provided.

While embodiments of the invention have been particularly shown and described with references to preferred embodiments thereof, it will be understood by those skilled in the art that various changes in form and details may be made herein without departing from the spirit and scope of the invention as defined by the appended claims.

What is claimed is:

1. A semiconductor device comprising:
a semiconductor chip including a first surface having bonding pads and a second surface opposite the first surface and having concave portions corresponding to the bonding pads;
a metal layer filling the concave portions and covering the second surface; and
solder balls for bump contacts provided on the bonding pads.

2. The semiconductor device of claim 1, wherein the corresponding concave portions and bonding pads are vertically arranged relative to the first surface.

3. The semiconductor device of claim 1, wherein the metal layer comprises a material selected from copper, aluminum, tungsten, nickel, gold, and silver, and alloys thereof.

4. The semiconductor device of claim 1, wherein a thickness of the semiconductor chip ranges from about 100 μm to about 200 μm.

5. The semiconductor device of claim 1, wherein a depth of each concave portion ranges from about 50 μm to about 150 μm.

6. A method of forming a semiconductor device, the method comprising:
preparing a semiconductor substrate where each of semiconductor chips including a first surface having bonding pads and a second surface opposite the first surface is formed;
back-lapping the second surface;
forming concave portions corresponding to the bonding pads on the second surface;
forming a metal layer that fills the concave portions and covers the second surface;
forming solder balls for bump contacts on the bonding pads; and
partitioning the metal layer and the semiconductor substrate to divide the semiconductor substrate into respective semiconductor devices.

7. The method of claim 6, further comprising:
attaching the semiconductor substrate to a handling substrate before back-lapping the second surface; and
removing the handling substrate after forming the metal layer.

8. The method of claim 6, wherein the semiconductor chips are formed to each have a thickness from about 100 μm to about 200 μm by the back-lapping the second surface.

9. The method of claim 6, wherein the corresponding concave portions and bonding pads are vertically arranged with respect to the first surface.

10. The method of claim 9, wherein the concave portions are formed using a process selected from ion etching, chemical etching, and laser etching.

11. The method of claim 10, wherein the concave portions are formed to have a depth from about 50 μm to about 150 μm.

12. The method of claim 6, wherein the metal layer comprises a material selected from copper, aluminum, tungsten, nickel, gold, and silver, and alloys thereof.

13. The method of claim 12, wherein the metal layer is formed using one selected from inkjet, screen-printing, and deposition.

14. A semiconductor device package comprising:
a semiconductor device, as claimed in claim 1;
a wiring board including a first surface to which the semiconductor device is mounted and a second surface opposite the first surface; and
an underfill material layer filling a space between a first surface of the semiconductor device and the first surface of the wiring board,
wherein the semiconductor device and the wiring board are electrically connected to each other by the solder balls for bump contacts of the semiconductor device and bonding electrodes included in the first surface of the wiring board.

15. The semiconductor device package of claim 14, further comprising solder balls for external connection provided on the second surface of the wiring board.

16. The semiconductor device package of claim 14, wherein the underfill material layer thoroughly covers side surfaces of a semiconductor chip of the semiconductor device.

17. A method of fabricating a semiconductor device package, the method comprising:
preparing a semiconductor device according to the method described in claim 6;
preparing a wiring board including a first surface having bonding electrodes corresponding to solder balls for bump contacts of the semiconductor device and a second surface opposite the first surface;
mounting the semiconductor device on the wiring board such that the solder balls for bump contacts of the semiconductor device are electrically connected to the bonding electrodes of the wiring board; and
forming an underfill material layer filling a space between a first surface of the semiconductor device and the first surface of the wiring board.

18. The method of claim 17, further comprising forming solder balls for external connection on the second surface of the wiring board.

19. The method of claim 17, wherein the underfill material layer is formed so as to thoroughly cover side surfaces of a semiconductor chip of the semiconductor device.
